(19) United States
(12) Patent Application Publication
(10) Pub. No.: US 2022/0190557 A1
(43) Pub. Date: Jun. 16, 2022

(54) LIGHT EMITTING DEVICE, MANUFACTURING METHOD, AND WAVEGUIDE STRUCTURE

(71) Applicant: Panasonic Intellectual Property Management Co., Ltd., Osaka (JP)

(72) Inventors: NAOYA RYOKI, Osaka (JP); YUKIO NISHIKAWA, Osaka (JP); TAKEHIRO ASAHI, Osaka (JP); YOSHIO OKAYAMA, Osaka (JP)

(21) Appl. No.: 17/512,632

(22) Filed: Oct. 27, 2021

(30) Foreign Application Priority Data
Dec. 14, 2020 (JP) 2020-207045

(51) Int. Cl. H01S 5/10; H01S 5/14; H01S 3/063

(52) U.S. Cl. CPC H01S 5/1014; H01S 3/063; H01S 5/147

(57) ABSTRACT

A light emitting device includes a light source that emits light having a directivity from a light emitting surface of the light source, a waveguide structure that includes an optical waveguide having an inlet facing the light emitting surface, and a peripheral wall protruding from the inlet toward the light emitting surface, and a lens that is provided between the light emitting surface and the inlet. The peripheral wall has an inner surface surrounding the inlet. The peripheral wall has a first opening closer to the light emitting surface and a second opening closer to the inlet. The first opening is larger than the second opening. The peripheral wall includes a narrow opening portion in which an internal space of the peripheral wall is smaller than the lens when viewed from a direction of an optical axis of the light. The inner surface of the peripheral wall includes an inclined surface that inclines so that the internal space becomes narrower as approaching the inlet, at least in the narrow opening portion. The lens is disposed in contact with the narrow opening portion in the internal space of the peripheral wall.

### BACKGROUND

### 1. Technical Field

The present disclosure generally relates to a light emitting device, a manufacturing method, and a waveguide structure. More specifically, the present disclosure relates to a light emitting device including a light source that emits light having directivity, a method for manufacturing the light emitting device, and a waveguide structure used for the light emitting device.

### 2. Description of the Related Art

Japanese Unexamined Patent Publication No. 7-270839 discloses an optical waveguide type SHG element as a light emitting device. In Japanese Unexamined Patent Publication No. 7-270839, the optical waveguide type SHG element is formed of a non-linear optical material. The non-linear optical material is configured with a channel waveguide, a segment waveguide, and a tapered waveguide. In Japanese Unexamined Patent Publication No. 7-270839, a laser beam is incident on the tapered waveguide by an objective lens. The light guided in the tapered waveguide is converted into single mode waveguide light by the channel waveguide and is incident on the segment waveguide.

### SUMMARY

According to an aspect of the present disclosure, there is provided a light emitting device including a light source, a waveguide structure, and a lens. The light source emits light having a directivity from a light emitting surface of the light source. The waveguide structure includes an optical waveguide and a peripheral wall. The optical waveguide includes an inlet facing the light emitting surface. The peripheral wall protrudes from the inlet toward the light emitting surface and has an inner surface surrounding the inlet. The peripheral wall has a first opening closer to the light emitting surface and a second opening closer to the inlet. The first opening is larger than the second opening. The lens is provided between the light emitting surface and the inlet. The peripheral wall includes a narrow opening portion in which an internal space of the peripheral wall is smaller than the lens when viewed from a direction of an optical axis of the light. The inner surface of the peripheral wall includes an inclined surface that inclines so that the internal space becomes narrower as approaching the inlet, at least in the narrow opening portion. The lens is disposed in contact with the narrow opening portion in the internal space of the peripheral wall.

According to an aspect of the present disclosure, there is provided a waveguide structure including an optical waveguide and a peripheral wall. The optical waveguide includes an inlet that faces a light emitting surface, from which light having a directivity is emitted, in a light source while interposing a lens therebetween. The peripheral wall protrudes from the inlet toward a side of the light emitting surface. The peripheral wall has an inner surface surrounding the inlet. The peripheral wall has a first opening closer to the light emitting surface and a second opening closer to the inlet. The first opening is larger than the second opening. The peripheral wall includes a narrow opening portion in which internal space is smaller than the lens when viewed from the direction of the optical axis of light. The inner surface of the peripheral wall includes an inclined surface that inclines so that the internal space becomes narrower as approaching the inlet, at least in the narrow opening portion.

### BRIEF DESCRIPTION OF THE DRAWINGS

FIG. 1 is a schematic cross-sectional view showing a configuration example of a light emitting device according to a first exemplary embodiment;

FIG. 2 is an explanatory view showing a configuration example of a waveguide structure of the light emitting device of FIG. 1;

FIG. 3 is a front view showing a state in which a lens is fitted to the waveguide structure of FIG. 1;

FIG. 4 is an explanatory view of a positional relationship between a light source and the lens of the light emitting device of FIG. 1;

FIG. 5 is an explanatory view of a first example of the positional relationship between the light source and the lens of the light emitting device of FIG. 1;

FIG. 6 is an explanatory view of an angle of an inclined surface of the waveguide structure of FIG. 1 in the first example shown in FIG. 5;

FIG. 7 is an explanatory view of a second example of the positional relationship between the light source and the lens of the light emitting device of FIG. 1;

FIG. 8 is an explanatory view of the angle of the inclined surface of the waveguide structure of FIG. 1 in the second example shown in FIG. 7;

FIG. 9 is an explanatory view of a third example of the positional relationship between the light source and the lens of the light emitting device of FIG. 1;

FIG. 10 is an explanatory view of the angle of the inclined surface of the waveguide structure of FIG. 1 in the third example shown in FIG. 9;

FIG. 11 is an explanatory view of a method for manufacturing the light emitting device of FIG. 1;

FIG. 12 is an explanatory view of an angle of an inclined surface of a waveguide structure of a second exemplary embodiment in the first example shown in FIG. 5;

FIG. 13 is an explanatory view of an angle of an inclined surface of the waveguide structure of the second exemplary embodiment in the second example shown in FIG. 7;

FIG. 14 is an explanatory view of the angle of the inclined surface of the waveguide structure of the second exemplary embodiment in the third example shown in FIG. 9;

FIG. 15 is a cross-sectional view of a configuration example of a waveguide structure of a first modification example;

FIG. 16 is a cross-sectional view of a configuration example of a waveguide structure of a second modification example; and

FIG. 17 is a cross-sectional view of a configuration example of a waveguide structure of a third modification example.

### DETAILED DESCRIPTIONS

In Japanese Unexamined Patent Publication No. 7-270839, it is not easy to position an objective lens for causing a laser beam to be incident on a tapered waveguide.

The present disclosure provides a light emitting device, a manufacturing method, and a waveguide structure, in which a lens can be easily positioned, so that it is possible to improve optical coupling efficiency.

Hereinafter, exemplary embodiments will be described in detail with reference to the appropriate drawings. However, there is a case where description which is more detail than necessary is omitted. For example, there is a case where detailed descriptions of already well-known matters and duplicate descriptions for substantially the same configuration are omitted. A reason for this is to avoid unnecessary redundancy of the following description and to facilitate understanding of those skilled in the art. The inventors (or others) provide the accompanying drawings and the following descriptions so that those skilled in the art fully understand the present disclosure, and do not intend to limit a subject matter described in the claims by the drawings and the descriptions.

### EXEMPLARY EMBODIMENTS

### 1. First Exemplary Embodiment

### 1-1. Overview

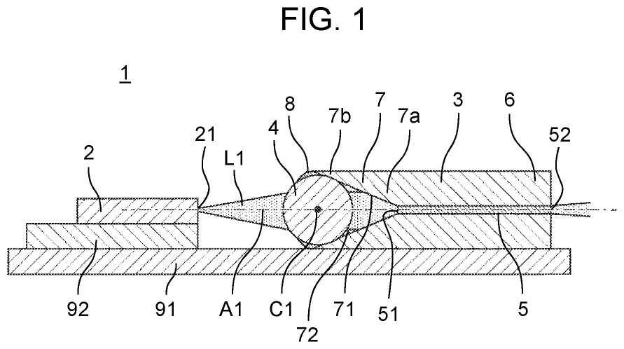

FIG. 1 is a cross-sectional view of a configuration example of light emitting device 1 according to the present exemplary embodiment. Light emitting device 1 of FIG. 1 includes light source 2, waveguide structure 3, and lens 4. Light source 2 emits light L1 having directivity from light emitting surface 21. Waveguide structure 3 includes optical waveguide 5 and peripheral wall 7. Optical waveguide 5 includes inlet 51 facing light emitting surface 21. Peripheral wall 7 protrudes from inlet 51 toward a side of light emitting surface 21. Peripheral wall 7 includes inner surface 71 surrounding inlet 51. In peripheral wall 7, an opening on the side of light emitting surface 21 is larger than an opening on a side of inlet 51. Lens 4 is provided between light emitting surface 21 and inlet 51. Peripheral wall 7 includes narrow opening portion 7a in which internal space 72 of peripheral wall 7 is smaller than lens 4 when viewed from a direction of optical axis A1 of light L1. At least in narrow opening portion 7a, inner surface 71 of peripheral wall 7 includes an inclined surface that inclines so that internal space 72 becomes narrower as approaching inlet 51. Lens 4 is disposed in contact with narrow opening portion 7a in internal space 72 of peripheral wall 7.

In light emitting device 1 of FIG. 1, lens 4 can be disposed in contact with narrow opening portion 7a in internal space 72 of peripheral wall 7. As a result, it is possible to easily position lens 4 with respect to waveguide structure 3. At least in narrow opening portion 7a, inner surface 71 of peripheral wall 7 includes the inclined surface that inclines so that internal space 72 becomes narrower as approaching inlet 51. As a result, there is a high possibility that it is possible to reflect light, which is not directly incident on inlet 51 of optical waveguide 5 among light L1 emitted from lens 4, by inner surface 71 of peripheral wall 7 and to be incident on inlet 51. As a result, it is possible to improve the optical coupling efficiency between light source 2 and waveguide structure 3 via lens 4. As above, in light emitting device 1 of FIG. 1, lens 4 can be easily positioned, so that it is possible to improve the optical coupling efficiency.

### 1-2. Details

Hereinafter, light emitting device 1 according to the present exemplary embodiment will be described in detail. As shown in FIG. 1, light emitting device 1 includes light source 2, waveguide structure 3, lens 4, base 91, and fitting member 92.

As shown in FIG. 1, light source 2 includes light emitting surface 21. Light source 2 emits light L1 from light emitting surface 21. Light L1 has directivity. In FIG. 1, light L1 travels along optical axis A1. In the present exemplary embodiment, light source 2 is a laser, for example, a semiconductor laser. Light L1 is a laser beam. A semiconductor laser has a low output compared as a laser or the like for processing but has a small in size. Therefore, it is possible to configure a small light emitting device by combining with a small optical system. A wavelength of light L1 is not limited to a wavelength in a visible light area, and may be a wavelength in an infrared area and a wavelength in an ultraviolet area.

As shown in FIG. 1, lens 4 is disposed between light source 2 and waveguide structure 3. More specifically, lens 4 is disposed between light emitting surface 21 of light source 2 and inlet 51 of optical waveguide 5, which will be described later, of waveguide structure 3. Light L1 emitted from light source 2 is incident on lens 4. Light L1 emitted from lens 4 faces toward inlet 51 of optical waveguide 5 of waveguide structure 3. Lens 4 is used to condense light from light source 2 to inlet 51. In the present exemplary embodiment, lens 4 is a spherical lens. As a result, in of lens 4, both a portion on the side of inlet 51 and a portion on the side of light emitting surface 21 are convex lenses. Lens 4 is disposed so that center C1 of lens 4 is provided on optical axis A1 of light L1.

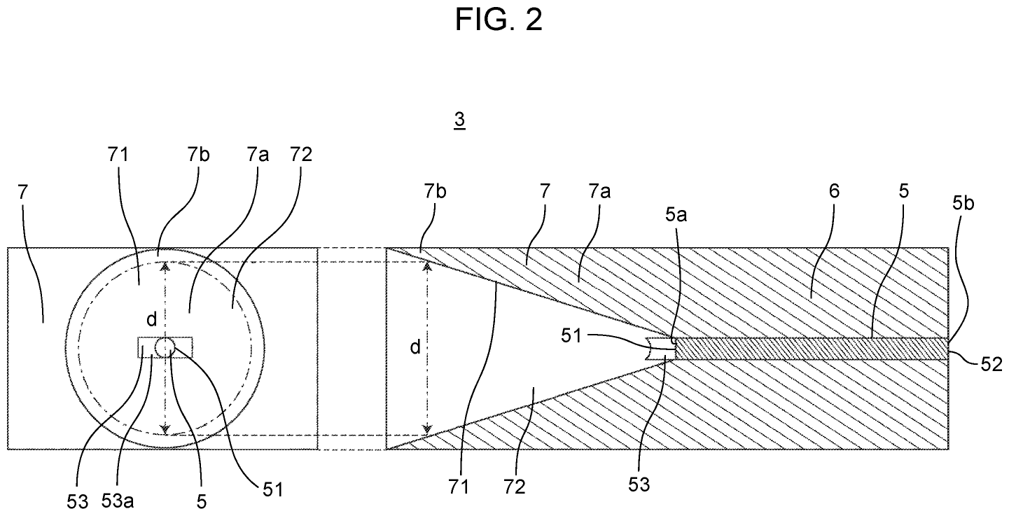

FIG. 2 shows a configuration example of waveguide structure 3. Waveguide structure 3 includes optical waveguide 5, exterior 6, and peripheral wall 7.

Optical waveguide 5 is a transmission path for light L1 from light source 2. Optical waveguide 5 has inlet 51 and outlet 52, and emits light, which is incident from inlet 51, from outlet 52. Optical waveguide 5 is formed of a material, which has a property of transmitting light, for example, an inorganic material such as quartz glass, silicon, a semiconductor including gallium nitride or aluminum nitride, or a polymer material such as a polyimide resin or a polyamide resin. Optical waveguide 5 in FIG. 2 has a rectangular parallelepiped shape. Optical waveguide 5 is disposed to transmit light L1 from light source 2 along a length direction of optical waveguide 5. A first side surface (a left side surface in FIG. 2) 5a of optical waveguide 5 in the length direction is exposed in peripheral wall 7. In the present exemplary embodiment, a portion configuring a bottom surface of peripheral wall 7 on first side surface 5a of optical waveguide 5 is used as inlet 51. Portion 53 configuring an inner side surface of peripheral wall 7 on first side surface 5a of optical waveguide 5 configures a part of peripheral wall 7 instead of inlet 51 of optical waveguide 5. Outlet 52 is a portion exposed from exterior 6 on a second side surface (a right side surface in FIG. 2) 5b of optical waveguide 5 in the length direction. In the present exemplary embodiment, the bottom surface of peripheral wall 7 has a circular shape, and inlet 51 configures an entire bottom surface of peripheral wall 7. In the present exemplary embodiment, inlet 51 is a portion in a circular shape at a center of first side surface 5a of optical waveguide 5. An entirety of second side surface 5b of optical waveguide 5 in the length direction is exposed from exterior 6. That is, the entirety of second side surface 5b configures outlet 52. As a result, outlet 52 has a rectangular shape. Inlet 51 has a rough surface. In a case where surface roughness of inlet 51 is approximately equal to or larger than the wavelength of light L1, reflectance of light L1 at inlet 51 is reduced, and light L1 is absorbed by optical waveguide 5. As the wavelength of light L1, a wavelength of approximately 0.15 μm to 10.6 μm is industrially put into practical use. In the present exemplary embodiment, the surface roughness of inlet 51 is larger than 0.2 μm and is equal to or less than 20 μm. The surface roughness is, for example, arithmetic average roughness (Ra). The surface roughness is not limited to the arithmetic average roughness (Ra) and may be evaluated by any of a maximum height (Ry), ten-point average roughness (Rz), an unevenness average interval (Sm), a local peak average interval (S), and a load length ratio (tp). Optical waveguide 5 is disposed so that a central axis of optical waveguide 5 coincides with optical axis A1 of light L1.

Exterior 6 covers optical waveguide 5. Exterior 6 of FIG. 2 covers optical waveguide 5 to expose inlet 51 and outlet 52 of optical waveguide 5. Exterior 6 has a rectangular parallelepiped shape. Exterior 6 covers optical waveguide 5 so that a length direction of exterior 6 coincides with an axial direction of optical waveguide 5, and inlet 51 and outlet 52 of optical waveguide 5 are respectively exposed on both surfaces of exterior 6 in a length direction. In the present exemplary embodiment, exterior 6 is made of a metal material, for example, stainless steel.

Peripheral wall 7 protrudes from inlet 51 toward the side of light emitting surface 21. Peripheral wall 7 of FIG. 2 protrudes from a surface of exterior 6, from which inlet 51 is exposed, to the side of light emitting surface 21. In FIG. 2, peripheral wall 7 is formed to be continuously integrated with exterior 6. As a result, peripheral wall 7 is formed of the same metal material as exterior 6.

Peripheral wall 7 of FIG. 2 has a tubular shape that surrounds inlet 51 over an entire circumference. Peripheral wall 7 includes inner surface 71 surrounding inlet 51. In peripheral wall 7, the opening on the side of light emitting surface 21 is larger than the opening on the side of inlet 51. A space surrounded by inner surface 71 of peripheral wall 7 is internal space 72 of peripheral wall 7. The opening of peripheral wall 7 on the side of inlet 51 is a space surrounded by an edge of inner surface 71 on the side of inlet 51. The opening of peripheral wall 7 on the side of light emitting surface 21 is a space surrounded by an edge of inner surface 71 on the side of light emitting surface 21. Inner surface 71 of peripheral wall 7 is the inclined surface that inclines so that internal space 72 becomes narrower as approaching inlet 51. An inclination of the inclined surface is predetermined. In FIG. 2, an entirety of inner surface 71 is an inclined surface. Internal space 72 has the same shape as lens 4 when viewed from a direction of the central axis of optical waveguide 5, that is, the direction of optical axis A1 of light L1. Lens 4 is the spherical lens and lens 4 has a perfect circular shape when viewed from the direction of optical axis A1 of light L1. Internal space 72 has the perfect circular shape when viewed from the direction of optical axis A1 of light L1. When viewed from the direction of optical axis A1, a center of internal space 72 and a center of inlet 51 coincide with each other. In the present exemplary embodiment, internal space 72 has a truncated cone shape. As shown in FIG. 2, a diameter of a cross section of internal space 72 is the minimum at an end of peripheral wall 7 on the side of inlet 51 and is the maximum at an end of peripheral wall 7 on a side opposite to inlet 51. A maximum value of the diameter of the cross section of internal space 72 is larger than diameter d of lens 4, and a minimum value of the diameter of the cross section of internal space 72 is smaller than diameter d of lens 4. Further, the minimum value of the diameter of the cross section of internal space 72 is set so that exterior 6 is not exposed to internal space 72 of peripheral wall 7. That is, the minimum value of the diameter of the cross section of internal space 72 of peripheral wall 7 is set so that the entire bottom surface of peripheral wall 7 becomes inlet 51 of optical waveguide 5. Therefore, light L1 transmitted through lens 4 can be efficiently guided to inlet 51 of optical waveguide 5.

As above, peripheral wall 7 includes narrow opening portion 7a in which internal space 72 of peripheral wall 7 is smaller than lens 4 when viewed from the direction of optical axis A1. Peripheral wall 7 includes wide opening portion 7b in which internal space 72 of peripheral wall 7 is larger than lens 4 when viewed from the direction of optical axis A1. In narrow opening portion 7a and wide opening portion 7b, inner surface 71 of peripheral wall 7 is an inclined surface that inclines so that internal space 72 becomes narrower as approaching inlet 51. In the present exemplary embodiment, in narrow opening portion 7a, inner surface 71 is used as a reflection surface that reflects at least a part of light L1 that passes through lens 4. At least in narrow opening portion 7a, inner surface 71 is preferably in a state in which the surface roughness of a mirror surface or the like is small. As a result, it is possible to efficiently reflect light L1 that passes through lens 4 at narrow opening portion 7a. In order to reflect light L1 with high efficiency, inner surface 71 of peripheral wall 7 is processed to be a mirror surface. Therefore, in the present exemplary embodiment, the inclined surface has a mirror surface property. The surface roughness of the inclined surface is equal to or less than 0.2 μm. In a case where the surface roughness of the inclined surface is equal to or less than 0.2 μm, the excellent mirror surface property can be obtained even in a case where the metal material of peripheral wall 7 is stainless steel.

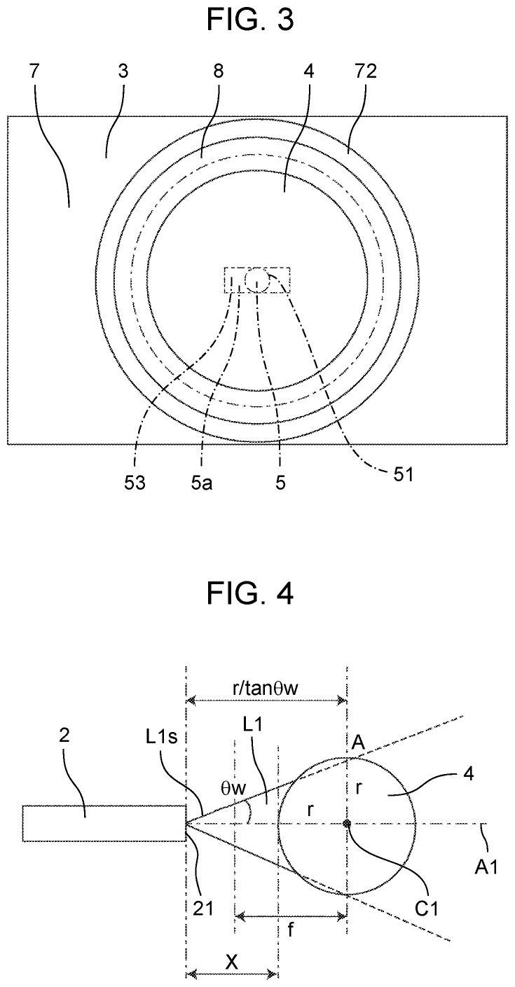

FIG. 3 is a front view showing a state in which lens 4 is fitted to waveguide structure 3. Lens 4 is disposed in contact with narrow opening portion 7a in internal space 72 of peripheral wall 7. As a result, it is possible to easily position lens 4 with respect to waveguide structure 3. Lens 4 and waveguide structure 3 are in contact with each other at narrow opening portion 7a of peripheral wall 7. In the present exemplary embodiment, lens 4 is the spherical lens and internal space 72 of peripheral wall 7 has the perfect circular shape when viewed from the direction of optical axis A1. Therefore, center C1 of lens 4 is positioned on optical axis A1 of light L1 only by inserting lens 4 into internal space 72 of peripheral wall 7. Since the shape of lens 4 is spherical, adjustment, such as tilting, is not necessary. Since Lens 4 and peripheral wall 7 thermally expands isotropically even in a case where a temperature changes, the optical axis and the like are hardly affected.

Lens 4 of FIG. 3 is fixed to waveguide structure 3 with adhesive 8. More specifically, adhesive 8 is disposed between lens 4 and wide opening portion 7b of peripheral wall 7. As a result, it is possible to reduce a possibility that adhesive 8 enters a space surrounded by inlet 51, peripheral wall 7, and lens 4. As a result, it is possible to reduce disturbance of the reflection of light L1 in the space surrounded by inlet 51, peripheral wall 7, and lens 4. The space surrounded by inlet 51, peripheral wall 7, and lens 4 is filled with gas. As a result, it is possible to reduce the disturbance of the reflection of light L1 in the space surrounded by inlet 51, peripheral wall 7, and lens 4.

As above, lens 4 is fixed to peripheral wall 7 of waveguide structure 3 with adhesive 8. In a case where lens 4 is fixed with adhesive 8, position shift is less likely to occur between lens 4 and waveguide structure 3 during the use of light emitting device 1, and it is possible to stabilize the optical coupling efficiency of light emitting device 1 for a long period of time. In a case of being fixed with adhesive 8, an external shape becomes small and cheap compared as a case of being mechanically fixed. Adhesive 8 is, for example, a relatively soft silicone-based adhesive. In this case, adhesive 8 can reduce influence of change due to thermal expansion and the like. As shown in FIG. 3, adhesive 8 is applied to surround lens 4 as a whole when viewed from the direction of optical axis A1. As a result, it is possible to more firmly fix lens 4 to waveguide structure 3 than a case where adhesive 8 is applied to partially surround lens 4 when viewed from the direction of optical axis A1. Therefore, the position shift is less likely to occur between lens 4 and waveguide structure 3. Further, it is possible to prevent invasion of minute foreign matters into the space surrounded by inlet 51, peripheral wall 7, and lens 4.

As shown in FIG. 1, base 91 supports light source 2, waveguide structure 3, and lens 4. Light source 2 is fitted to base 91 by fitting member 92. Fitting member 92 is used for adjusting a height of light source 2 and cooling light source 2. Fitting member 92 is fixed to base 91 with the adhesive or the like. Lens 4 is fixed to waveguide structure 3. Waveguide structure 3 is disposed on base 91 so that inlet 51 of optical waveguide 5 of waveguide structure 3 faces light emitting surface 21 of light source 2 via lens 4. Waveguide structure 3 is fixed to base 91 with an adhesive or the like.

### 1-3. Positional Relationship Between Light Source and Lens

Next, a positional relationship between light source 2 and lens 4 will be described. FIG. 4 is an explanatory view of the positional relationship between light source 2 and lens 4 of light emitting device 1. In FIG. 4, f indicates a focal distance of lens 4, and r indicates a radius of lens 4.

Light source 2 emits light L1 having directivity. In the present exemplary embodiment, light L1 is the laser beam. The laser beam is generally considered to have excellent straightness, but the laser beam travels while spreading. In FIG. 4, L1s indicates light traveling in a direction in which an angle with respect to optical axis A1 is the largest. An angle of light L1s with respect to optical axis A1 is set as a spread angle θw of light L1. In general, a semiconductor laser is considered to have a large spread angle θw in the laser light source, and have a spread of approximately 5 to 20° in a vertical direction and approximately 5 to 10° in a horizontal direction. In a case where spread angle θw of light L1 is taken into consideration and light source 2 and lens 4 are disposed so that light L1 does not leak to an outside of lens 4, it is possible to effectively utilize whole light L1 and it is possible to further enhance the optical coupling efficiency of light emitting device 1.

Light source 2 and lens 4 are closest to each other in a case where light source 2 and lens 4 are in contact with each other. In this case, x=0 in a case where x is set as a distance from light emitting surface 21 of light source 2 to lens 4 on optical axis A1 of light L1. Light source 2 is farthest from lens 4 in a range in which light L1 substantially falls in lens 4 in a case where an extension line of light L1s, which is an outer edge of light L1, passes through point A shown in FIG. 4. Point A is a point that is separated from center C1 of lens 4 by radius r of lens 4 to be perpendicular to optical axis A1. In this case, x is represented as x=(r/tan θw)−r=r{(1/tan θw)−1}. Therefore, light source 2 and lens 4 are disposed so that distance x from light emitting surface 21 of light source 2 on optical axis A1 of light L1 to lens 4 satisfies 0≤x<r{(1/tan θw)−1}. As a result, light L1 is less likely to leak to the outside of lens 4.

### 1-4. Angle of Inclined Surface of Peripheral Wall

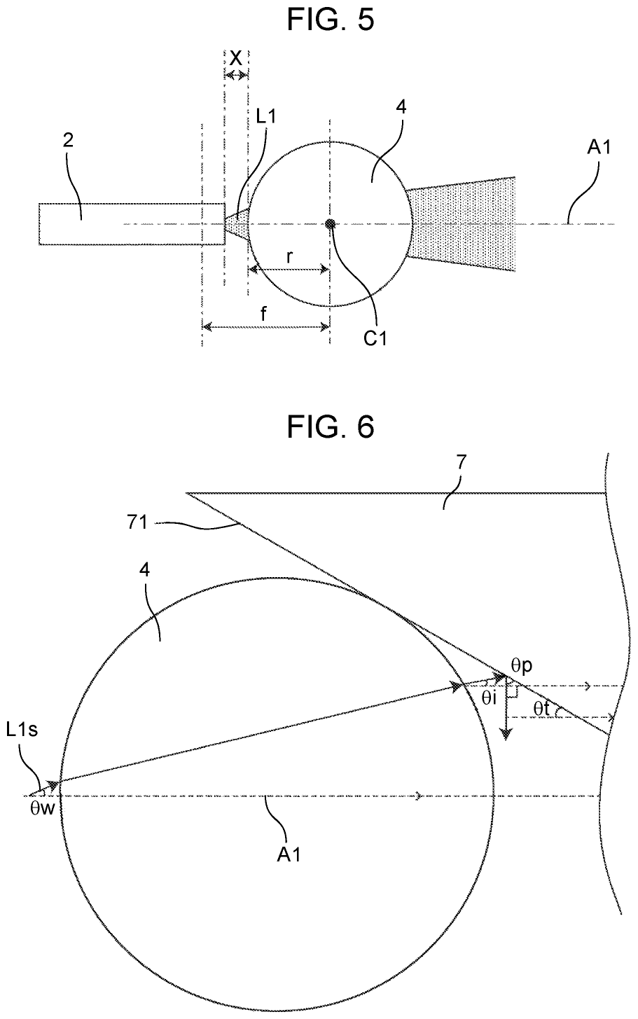

In the present exemplary embodiment, in narrow opening portion 7a, inner surface 71 of peripheral wall 7 is the inclined surface that inclines so that internal space 72 becomes narrower as approaching inlet 51. In the following description, inner surface 71 is referred to as inclined surface 71. In narrow opening portion 7a, inclined surface 71 is used as the reflection surface that reflects at least a part of light L1 that passes through lens 4. Here, an angle of inclined surface 71 of peripheral wall 7, at which it is possible to more efficiently guide light L1 to inlet 51 of optical waveguide 5, with respect to optical axis A1 is different according to distance x from light emitting surface 21 of light source 2 to lens 4 on optical axis A1 of light L1. Hereinafter, setting of the angle of inclined surface 71 will be described with reference to FIGS. 5 to 10.

FIG. 5 is an explanatory view of a first example of the positional relationship between light source 2 and lens 4 of light emitting device 1. FIG. 6 is an explanatory view of the angle of inclined surface 71 of waveguide structure 3 in the first example. In the first example, light emitting surface 21 of light source 2 is in a range of a focal distance f from the center of lens 4. In the first example, x satisfies 0≤x<f−r. Therefore, light L1 emitted from light emitting surface 21 of light source 2 is condensed by lens 4 but travels while still spreading. In FIG. 6, an angle between a direction in which light L1s corresponding to the outer edge of light L1 travels after being emitted from lens 4 and optical axis A1 is denoted by Oi. Light L1s is reflected by inclined surface 71 of peripheral wall 7 after being emitted from lens 4. Here, in a case where a traveling direction of light L1s reflected by inclined surface 71 is orthogonal to optical axis A1, it is considered that light L1s is not incident on inlet 51 of optical waveguide 5. In a case where an angle of the traveling direction of light L1s with respect to inclined surface 71 at this time is denoted by θp, θp={180°−(90°−θi}/2=45°+θi/2. In a case where the angle of inclined surface 71 with respect to optical axis A1 is denoted by θt, θt=90°−θp=90°−(45°+θi/2)=45°−θi/2. θi changes according to x. In a case where light source 2 is closest to lens 4, x≈0 and θi≤θw. In a case where light emitting surface 21 of light source 2 is in the vicinity of a position of the focal distance f from center C1 of lens 4, x≈f−r and θi≈0°. As a result, θi is approximately expressed as θi≤{(f−r−x)/(f−r)}θw={1−x/(f−r)}θw. Therefore, a range of angle θt of inclined surface 71, on which light L1s is guided to inlet 51, is expressed by the following Equation (1).

$$0 ° < θ t < 45 ° - ( 1 - \frac{x}{f - r} ) \times \frac{θ w}{2} \qquad ( 1 )$$

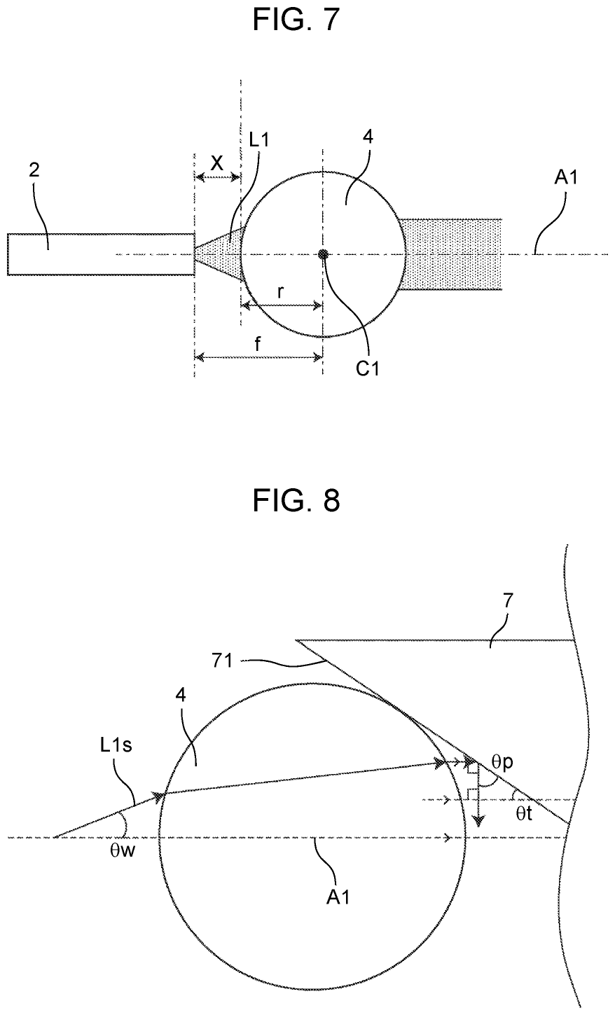

FIG. 7 is an explanatory view of a second example of the positional relationship between light source 2 and lens 4 of light emitting device 1. FIG. 8 is an explanatory view of angle θt of inclined surface 71 of waveguide structure 3 of the second example. In the second example, light emitting surface 21 of light source 2 is at the position of focal distance f from center C1 of lens 4. In the second example, x=f−r. Therefore, light L2 emitted from light emitting surface 21 of light source 2 is condensed by lens 4 and becomes substantially parallel light. In FIG. 8, light L1s corresponding to the outer edge of light L1 is reflected by inclined surface 71 of peripheral wall 7 after being emitted from lens 4. Angle θp in this case is expressed as θp=(180°−90°)/2=45°. Angle θt of inclined surface 71 in this case is expressed as θt=90°−θp=45°. Therefore, the range of angle θt of inclined surface 71, on which light L1s is guided to inlet 51, is expressed as 0°<θt<45°.

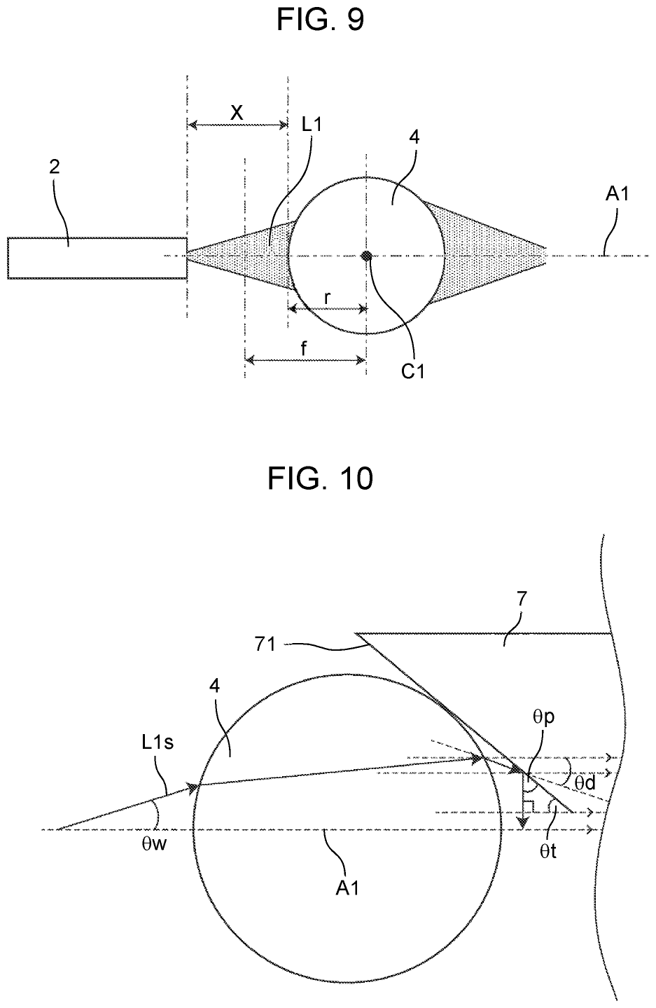

FIG. 9 is an explanatory view of a third example of the positional relationship between light source 2 and lens 4 of light emitting device 1. FIG. 10 is an explanatory view of the angle of inclined surface 71 of waveguide structure 3 in the third example. In the third example, light emitting surface 21 of light source 2 is out of the range of the focal distance f from the center of lens 4. In the third example, x satisfies f−r<x<r{(1/tan θw)−1}. Therefore, light L1 emitted from light emitting surface 21 of light source 2 is condensed by lens 4 and travels while narrowing. In FIG. 10, the angle between the direction in which light L1s corresponding to the outer edge of light L1 travels after being emitted from lens 4 and optical axis A1 is denoted by θd. Angle θp in this case is expressed as θp=(180°−90°−θd)/2=45°−θd/2. Angle θt of inclined surface 71 in this case is expressed as θt=90°−θp=90°−(45°−θd/2)=45°+θd/2. θd changes according to x. In a case where light source 2 is the farthest from lens 4 in a range where x satisfies f−r<x<r{(1/tan θw)−1}, x≈r{(1/tan θw)−1} and θd≥θw. In the case where light emitting surface 21 of light source 2 is in the vicinity of the position of focal distance f from center C1 of lens 4, x≈f−r and θd≈0°. As a result, θd is approximately expressed as θd≥(x−(f−r))/(r(1/tan θw−1)−(f−r))θw=(x−f+r)/(r/tan θw−f)θw. Therefore, the range of angle θt of inclined surface 71, on which light L1s is guided to inlet 51, is expressed by the following Equation (2).

$$0 ° < θ t < 45 ° + \frac{x - f + r}{\frac{r}{tan θ w} - f} \times \frac{θ w}{2} \qquad ( 2 )$$

From the above, in a case where x satisfies 0≤x<f−r, θt is denoted by satisfy the Equation (1). In a case where x satisfies f−r<x<r{(1/tan θw)−1}, θt is denoted by satisfy the Equation (2). As a result, it is possible to guide light L1 to optical waveguide 5 by inclined surface 71.

With the configuration, it is possible to efficiently guide light L1 to optical waveguide 5 by using the reflection on inclined surface 71. Therefore, it is not necessary to make precise adjustments in XYZ triaxial directions of light source 2, lens 4, and waveguide structure 3, and it is possible to suppress cost required for a structure of light emitting device 1 and manufacture of light emitting device 1, and, further, it is possible to improve the optical coupling efficiency. Further, even in a case where a semiconductor laser having individual spread angle θw is used as light source 2, it is possible to cause light L1 to be stably converged and incident on inlet 51 of optical waveguide 5, so that it is possible to reduce variation in the optical coupling efficiency.

### 1-5. Manufacturing Method

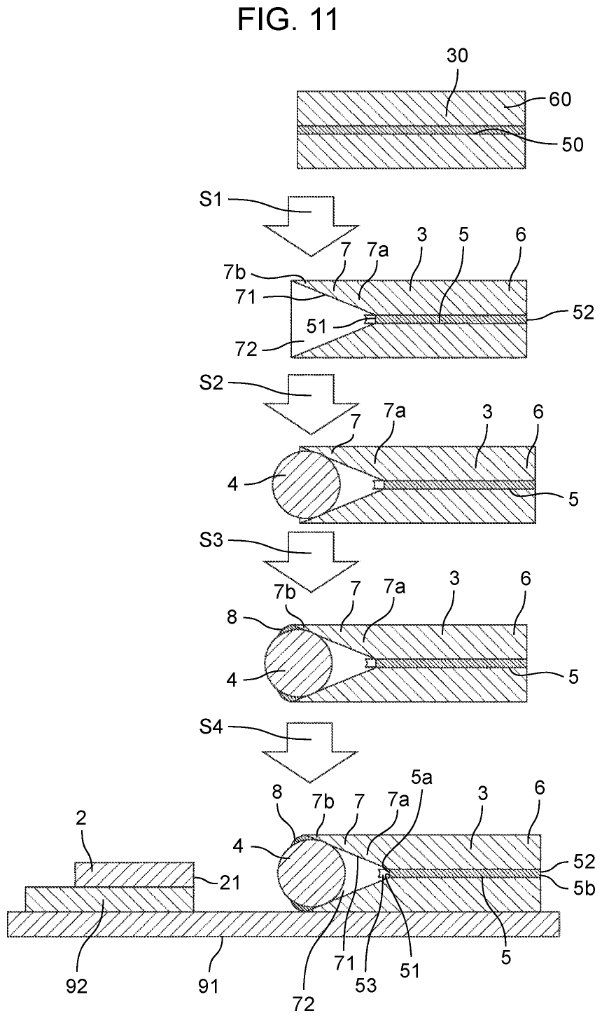

Next, a manufacturing method for manufacturing light emitting device 1 of FIG. 1 will be described with reference to FIG. 11. The manufacturing method shown in FIG. 11 includes step S1 for forming waveguide structure 3, step S2 for disposing lens 4, step S3 for fixing lens 4, and step S4 for disposing light source 2 and waveguide structure 3.

In step S1, waveguide structure 3 is formed from structure 30 that is a base of waveguide structure 3. Structure 30 includes light transmitting portion 50 and covering portion 60 that covers light transmitting portion 50. Light transmitting portion 50 is a base of optical waveguide 5. Light transmitting portion 50 is formed of a material having a property of transmitting light, for example, an inorganic material such as a semiconductor including quartz glass, silicon, gallium nitride or aluminum nitride, or a polymer material such as a polyimide resin or a polyamide resin. Light transmitting portion 50 in FIG. 11 has a rectangular parallelepiped shape. Covering portion 60 serves as a base for exterior 6 and peripheral wall 7. Covering portion 60 covers light transmitting portion 50. Covering portion 60 of FIG. 11 has a rectangular parallelepiped shape. Covering portion 60 covers light transmitting portion 50 so that a length direction of covering portion 60 coincides with an axial direction of light transmitting portion 50, and both ends of light transmitting portion 50 in the axial direction are respectively exposed on both sides of covering portion 60 in the length direction. Covering portion 60 is formed of a metal material, for example, stainless steel.

In step S1, one surface of structure 30 in the length direction is processed to remove some parts of light transmitting portion 50 and covering portion 60, so that a recess corresponding to internal space 72 of peripheral wall 7 is formed. As a result, waveguide structure 3 is obtained. In waveguide structure 3 of FIG. 1, internal space 72 has the truncated cone shape. Therefore, in a case where a conical tool is rotated around the axis of light transmitting portion 50, a truncated cone-shaped recess is formed on one surface of structure 30 in the length direction. Thereafter, surface processing is performed on an inner surface of the recess with a relatively fine tool. As a result, it is possible to give the mirror surface property to a side surface of the recess which is inner surface 71 of peripheral wall 7. Further, the surface processing is performed on an end surface of light transmitting portion 50 exposed in the recess with the relatively fine tool. As a result, it is possible to leave concentric machining marks by the conical tool on the end surface of light transmitting portion 50 exposed to the recess, which is an inlet of optical waveguide 5, so that it is possible to make the surface rough. As a result, it is possible to cause optical waveguide 5 to absorb light L1 with high efficiency. Other precise processing methods may be used for processing structure 30. In this case, processing marks may have other shapes, such as crossed shapes, instead of the concentric circles.

In step S2, lens 4 is disposed so that lens 4 is in contact with narrow opening portion 7a in internal space 72 of peripheral wall 7 of waveguide structure 3. In the present exemplary embodiment, lens 4 is the spherical lens and internal space 72 of peripheral wall 7 has the perfect circular shape when viewed from the direction of optical axis A1. Therefore, center C1 of lens 4 is positioned on optical axis A1 of light L1 only by inserting lens 4 into internal space 72 of peripheral wall 7. Since the shape of lens 4 is spherical, adjustment, such as tilting, is not necessary. Lens 4 is selected so that the amount of light L1 emitted from waveguide structure 3 is maximized.

In step S3, lens 4 is fixed to waveguide structure 3 with adhesive 8. Adhesive 8 is disposed between lens 4 and wide opening portion 7b of peripheral wall 7. As a result, it is possible to reduce the possibility that adhesive 8 enters the space surrounded by inlet 51, peripheral wall 7, and lens 4. The space surrounded by inlet 51, peripheral wall 7, and lens 4 is filled with gas. Adhesive 8 is applied to surround lens 4 as a whole when viewed from the direction of optical axis A1. As a result, it is possible to more firmly fix lens 4 to waveguide structure 3 than the case where adhesive 8 is applied to partially surround lens 4 when viewed from the direction of optical axis A1. Therefore, the position shift is less likely to occur between lens 4 and waveguide structure 3. Further, it is possible to prevent invasion of minute foreign matters into the space surrounded by inlet 51, peripheral wall 7, and lens 4.

In step S4, light source 2 is fitted to base 91 by fitting member 92. Fitting member 92 is used for adjusting the height of light source 2 and cooling light source 2. Fitting member 92 is fixed to base 91 with the adhesive or the like. Further, in step S4, waveguide structure 3 is disposed on base 91 so that inlet 51 of optical waveguide 5 of waveguide structure 3 faces light emitting surface 21 of light source 2 via lens 4. After light L1 passes through lens 4, light L1 is reflected by the inclined surface formed in waveguide structure 3 and is guided to inlet 51 of optical waveguide 5. In step S4, a position of waveguide structure 3 is adjusted and installed so that the amount of light L1 emitted from waveguide structure 3 is maximized. In step S4, since lens 4 is fixed to waveguide structure 3, a work of adjusting the position of waveguide structure 3 is equivalent to a work of adjusting the positional relationship between light source 2 and lens 4. After the position of waveguide structure 3 is determined with respect to light source 2, waveguide structure 3 is fixed to base 91 by an adhesive or the like.

With above steps S1 to S4, light emitting device 1 shown in FIG. 1 is obtained.

### 1-6. Effects

Light emitting device 1 described above includes light source 2, waveguide structure 3, and lens 4. Light source 2 emits light L1 having directivity from light emitting surface 21. Waveguide structure 3 includes optical waveguide 5 and peripheral wall 7. Optical waveguide 5 includes inlet 51 facing light emitting surface 21. Peripheral wall 7 protrudes from inlet 51 toward the side of light emitting surface 21. Peripheral wall 7 includes inner surface 71 surrounding inlet 51. In peripheral wall 7, the opening on the side of light emitting surface 21 is larger than the opening on the side of inlet 51. Lens 4 is provided between light emitting surface 21 and inlet 51. Peripheral wall 7 includes narrow opening portion 7a whose internal space 72 is smaller than lens 4 when viewed from the direction of optical axis A1 of the light L1. At least in narrow opening portion 7a, inner surface 71 of peripheral wall 7 includes the inclined surface that inclines so that internal space 72 becomes narrower as approaching inlet 51. Lens 4 is disposed in contact with narrow opening portion 7a in internal space 72 of peripheral wall 7.

Light L1, such as the laser beam, having directivity, is generally considered to have excellent straightness, but in reality, Light L1 travels while spreading at a predetermined angle in many cases. Light L1 spreading to an outside of waveguide structure 3 does not enter optical waveguide 5 and becomes a loss, so that the optical coupling efficiency is lowered. Light emitting device 1 of FIG. 1 includes lens 4, so that light L1 can be condensed by lens 4. Therefore, an allowable range of a position of light emitting surface 21, which can cause all light L1 to be incident on waveguide structure 3, increases, so that it is possible to efficiently use light L1. Further, since waveguide structure 3 has the inclined surface which inclines to optical waveguide 5, light L1 emitted from lens 4 is reflected by the inclined surface and travels toward inlet 51 of optical waveguide 5 without leaking to an outside of peripheral wall 7, thereby being guided to optical waveguide 5. As above, peripheral wall 7 causes lens 4 to be positioned in such a way that inner surface 71 of peripheral wall 7 is in contact with lens 4, and inner surface 71 of peripheral wall 7 includes the inclined surface, which inclines to be separated from inlet 51 as facing light emitting surface 21 from inlet 51, between a contact portion of at least lens 4 and inner surface 71 of peripheral wall 7 and inlet 51.

As a result, light L1 is efficiently guided from light source 2 to optical waveguide 5, so that it is possible to improve the optical coupling efficiency. Further, since lens 4 and waveguide structure 3 are in contact with each other, it is extremely easy to position lens 4 and waveguide structure 3 on optical axis A1 of light L1, so that the optical coupling efficiency is improved while it is not necessary to make precise adjustment in the XYZ triaxial directions.

As above, according to light emitting device 1 of FIG. 1, lens 4 can be easily positioned, so that it is possible to improve the optical coupling efficiency.

Further, a portion of lens 4 on the side of the inlet is a convex lens. As a result, lens 4 can be easily positioned, so that it is possible to improve the optical coupling efficiency. Internal space 72 has the same shape as lens 4 when viewed from the direction of optical axis A1. As a result, lens 4 can be easily positioned, so that it is possible to improve the optical coupling efficiency. Lens 4 has the perfect circular shape when viewed from the direction of optical axis A1. Internal space 72 has the perfect circular shape when viewed from the direction of optical axis A1. When viewed from the direction of optical axis A1, the center of internal space 72 and the center of inlet 51 coincide with each other. As a result, lens 4 can be easily positioned, so that it is possible to improve the optical coupling efficiency.

Further, lens 4 is a spherical lens. As a result, lens 4 can be easily positioned, so that it is possible to improve the optical coupling efficiency.

Further, in a case where the distance from light emitting surface 21 of light source 2 to lens 4 on optical axis A1 of light L1 is denoted by x, the spread angle of light L1 is denoted by θw, and the radius of lens 4 is denoted by r, x satisfies that 0≤x<r{1/tan θw−1}. As a result, it is possible to improve the light coupling efficiency.

Further, in a case where the angle of the inclined surface of light L1 with respect to optical axis A1 is denoted by θt and the focal distance of lens 4 is denoted by f, x satisfies 0≤x<f−r and θt satisfies the following Equation.

$$0 ° < θ t < 45 ° - ( 1 - \frac{x}{f - r} ) \times \frac{θ w}{2} \qquad$$

As a result, it is possible to improve the light coupling efficiency.

Further, in a case where the angle of the inclined surface of light L1 with respect to optical axis A1 is denoted by θt and the focal distance of lens 4 is denoted by f, x satisfies f−r≤x<r{1/tan θw−1} and θt satisfies the following Equation.

$$0 ° < θ t < 45 ° + \frac{x - f + r}{\frac{r}{tan θ w} - f} \times \frac{θ w}{2}$$

As a result, it is possible to improve the light coupling efficiency.

Further, the entirety of inner surface 71 of peripheral wall 7 is an inclined surface 71. As a result, it is possible to simplify the structure of waveguide structure 3, and it is possible to reduce manufacturing cost of light emitting device 1.

Further, inlet 51 has a rough surface. As a result, it is possible to improve an absorption efficiency of optical waveguide 5 with respect to light L3. The surface roughness of inlet 51 is larger than 0.2 μm and is equal to or less than 20 μm. As a result, it is possible to improve the absorption efficiency of optical waveguide 5 with respect to light L3.

Further, inclined surface 71 has the mirror surface property. As a result, it is possible to improve reflection efficiency of inclined surface 71 with respect to light L3. Surface roughness of inclined surface 71 is equal to or less than 0.2 μm. As a result, it is possible to improve the reflection efficiency of inclined surface 71 with respect to light L3.

Further, light source 2 is the semiconductor laser, and light L1 is laser beam L1. As a result, it is possible to miniaturize light emitting device 1.

Further, lens 4 is fixed to waveguide structure 3 with adhesive 8. As a result, the position shift between lens 4 and waveguide structure 3 is less likely to occur during the use of light emitting device 1, and it is possible to stabilize the optical coupling efficiency of light emitting device 1 for a long period of time. Adhesive 8 is applied to surround lens 4 as a whole when viewed from the direction of optical axis A1. As a result, the position shift between lens 4 and waveguide structure 3 is less likely to occur, and it is possible to prevent invasion of a minute foreign matter into the space surrounded by inlet 51, peripheral wall 7, and lens 4. Peripheral wall 7 includes wide opening portion 7b in which internal space 72 is larger than lens 4 when viewed from the direction of optical axis A1 of light L1. Adhesive 8 is disposed between lens 4 and wide opening portion 7b of peripheral wall 7. As a result, it is possible to reduce the disturbance of the reflection of light L1 in the space surrounded by inlet 51, peripheral wall 7, and lens 4.

Further, the space surrounded by inlet 51, peripheral wall 7, and lens 4 is filled with gas. As a result, it is possible to reduce the disturbance of the reflection of light L1 in the space surrounded by inlet 51, peripheral wall 7, and lens 4.

The manufacturing method described above is a manufacturing method for manufacturing light emitting device 1, and includes disposing lens 4 so that lens 4 is in contact with narrow opening portion 7a in internal space 72 of peripheral wall 7 of waveguide structure 3 (S2), and disposing waveguide structure 3 so that inlet 51 of optical waveguide 5 of waveguide structure 3 faces light emitting surface 21 of light source 2 via lens 4 (S4). As a result, lens 4 can be easily positioned, so that it is possible to improve the optical coupling efficiency.

Waveguide structure 3 described above includes optical waveguide 5 and peripheral wall 7. Optical waveguide 5 includes inlet 51 that faces light emitting surface 21, from which light L1 having directivity is emitted, in light source 2 while interposing lens 4 therebetween. Peripheral wall 7 protrudes from inlet 51 toward the side of light emitting surface 21. Peripheral wall 7 includes inner surface 71 surrounding inlet 51. In peripheral wall 7, the opening on the side of light emitting surface 21 is larger than the opening on the side of inlet 51. Peripheral wall 7 includes narrow opening portion 7a whose internal space 72 is smaller than lens 4 when viewed from the direction of optical axis A1 of the light L1. At least in narrow opening portion 7a, inner surface 71 of peripheral wall 7 includes inclined surface 71 that inclines so that internal space 72 becomes narrower as approaching inlet 51. As a result, lens 4 can be easily positioned, so that it is possible to improve the optical coupling efficiency.

### 2. Second Exemplary Embodiment

### 2.1 Configuration

A light emitting device according to a second exemplary embodiment has the same structure as light emitting device 1 of FIG. 1, but is different from light emitting device 1 of FIG. 1 in that peripheral wall 7 is not made of a metal material and has light transmission. Also in the present exemplary embodiment, since peripheral wall 7 is formed of the same material as exterior 6, exterior 6 also has light transmission. Examples of the material of peripheral wall 7 include an oxide material. Examples of the oxide material include vitreous synthetic quartz and sapphire.

In a case where peripheral wall 7 is not formed of a metal material and has light transmission, angle θt of inclined surface 71 is set so that light L1 transmitted through lens 4 does not pass through peripheral wall 7 and inclined surface 71 totally reflects light L1 transmitted through lens 4. That is, inclined surface 71 of peripheral wall 7 of the present exemplary embodiment is different from inclined surface 71 of peripheral wall 7 of the first exemplary embodiment in that critical angle θc is provided for total reflection. In the present exemplary embodiment, in order to guide light L1 to optical waveguide 5, angle θt is denoted by satisfy the following condition in which light L1 totally reflected by inclined surface 71, in addition to Equations (1) and (2) shown in the first exemplary embodiment. In a case where a refractive index of the material of peripheral wall 7 is denoted by n and the angle of incidence of light L1 on inclined surface 71 is denoted by θ, the condition of the total reflection is expressed as sin θ>sin θc=1/n. Therefore, θ>arcsin(1/n).

As described with reference to FIG. 4, in a range of distance x between light emitting surface 21 of light source 2 and lens 4 on optical axis A1 of light L1, a relationship between angle θt of inclined surface 71, which can guide light L1 to waveguide structure 3, and incident angle θ differs according to distance x. Similar to the first exemplary embodiment, a condition to be satisfied by angle θt will be described below according to the relationship between the position of light emitting surface 21 of light source 2 with respect to center C1 of lens 4 and the focal distance f of lens 4.

FIG. 12 is an explanatory view of angle θt of inclined surface 71 of waveguide structure 3 in the first example shown in FIG. 5. As described above, in the first example, light emitting surface 21 of light source 2 is in the focal distance f from the center of lens 4. In the first example, x satisfies 0≤x<f−r. Therefore, light L1 emitted from light emitting surface 21 of light source 2 is condensed by lens 4 but travels while still spreading. In FIG. 12, the angle between the direction in which light L1s corresponding to the outer edge of light L1 travels after being emitted from lens 4 and optical axis A1 is denoted by θi. Light L1s is incident on inclined surface 71 of peripheral wall 7 after being emitted from lens 4. A relationship between incident angle θ and angle θt of inclined surface 71 is expressed as θt=180°−θ−90°−θi=90°−θ−θi. Since a condition of total reflection is θ>arcsin(1/n), θt<90°−arcsin(1/n)−θi. θi changes according to x and is expressed as θi≤{(f−r−x)/(f−r)}θw={1−x/(f−r)}θw as in the first exemplary embodiment. Therefore, the range of angle θt of inclined surface 71, on which light L1s is totally reflected by inclined surface 71, is expressed by the following Equation (3).

$$0 ° < θ t < 90 ° - arcsin \frac{1}{n} - ( 1 - \frac{x}{f - r} ) \times θ w \qquad ( 3 )$$

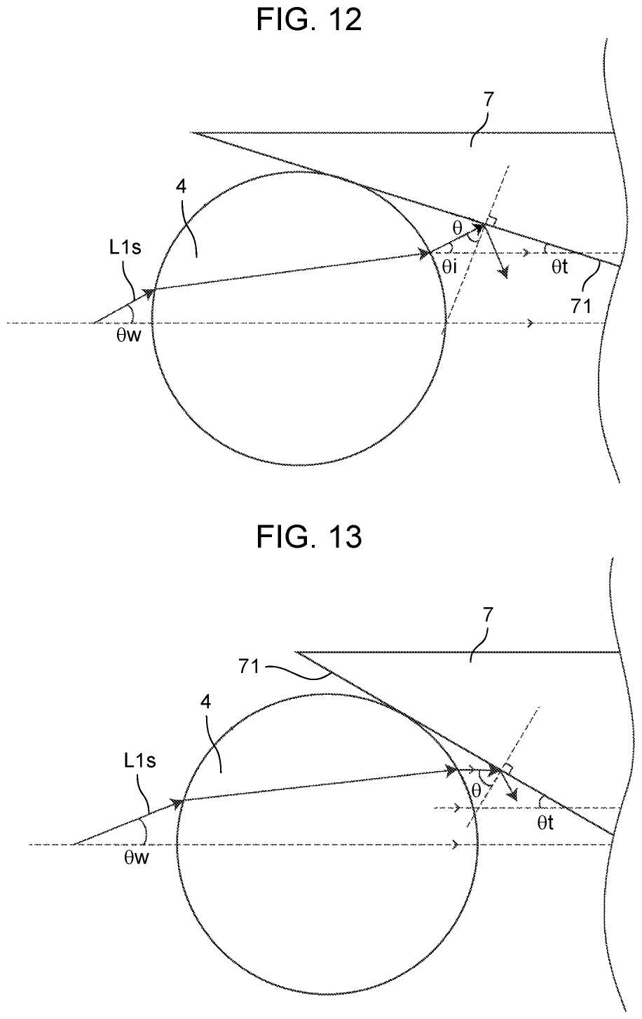

FIG. 13 is an explanatory view of angle θt of inclined surface 71 of waveguide structure 3 according to the second example shown in FIG. 7. In the second example, light emitting surface 21 of light source 2 is at the position of focal distance f from center C1 of lens 4. In the second example, x=f−r. Therefore, light L2 emitted from light emitting surface 21 of light source 2 is condensed by lens 4 and becomes substantially parallel light. In FIG. 13, light L1s corresponding to the outer edge of light L1 is reflected by inclined surface 71 of peripheral wall 7 after being emitted from lens 4. The relationship between incident angle θ and angle θt of inclined surface 71 is expressed as θt=180°−θ−90°=90°−θ. Since the condition of the total reflection is θ>arcsin(1/n), θt<90°−arcsin(1/n). Therefore, the range of angle θt of inclined surface 71, on which light L1s is totally reflected by inclined surface 71, is 0°<θt<90°−arcsin(1/n).

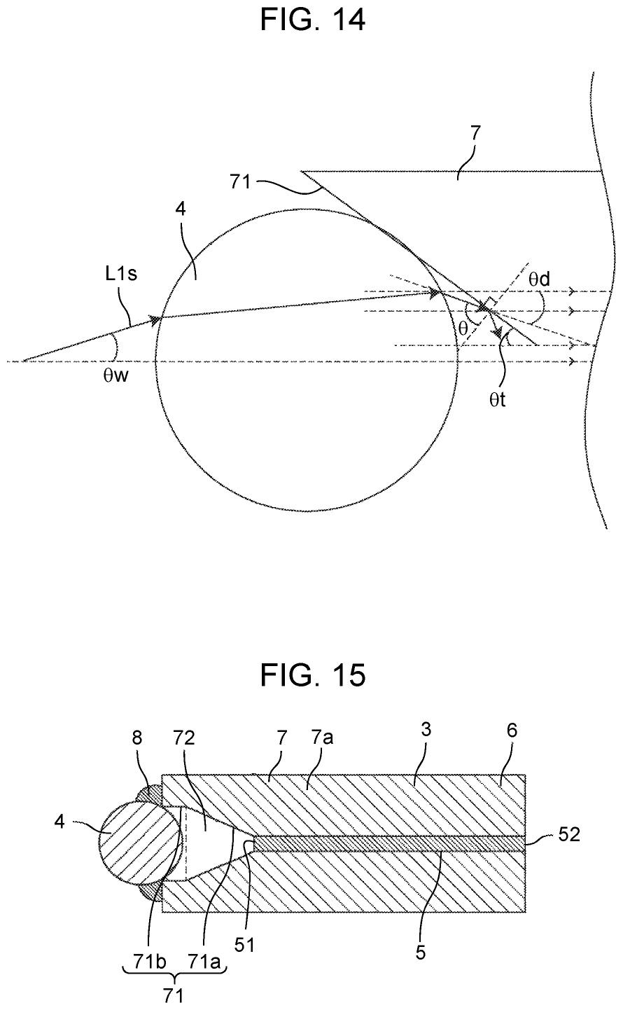

FIG. 14 is an explanatory view of angle θt of inclined surface 71 of waveguide structure 3 in the third example shown in FIG. 9. In the third example, light emitting surface 21 of light source 2 is out of the range of the focal distance f from the center of lens 4. In the third example, x satisfies f−r<x<r{(1/tan θw)−1}. Therefore, light L1 emitted from light emitting surface 21 of light source 2 is condensed by lens 4 and travels while narrowing. In FIG. 14, light L1s corresponding to the outer edge of light L1 is reflected by inclined surface 71 of peripheral wall 7 after being emitted from lens 4. The relationship between incident angle θ and angle θt of inclined surface 71 is expressed as θt=180°−90°−(θ−θd)=90°−θ+θd. Since the condition of the total reflection is θ>arcsin(1/n), θt<90°−arcsin(1/n)+θd. θd changes according to x and is expressed as θd≥(x−(f−r))/(r(1/tan θw−1)−(f−r))θw=(x−f+r)/(r/tan θw−f)θw as in the first exemplary embodiment. Therefore, the range of angle θt of inclined surface 71, on which light L1s is totally reflected by inclined surface 71, is expressed by the following Equation (4).

$$0 ° < θ t < 90 ° - arcsin \frac{1}{n} + \frac{x - f + r}{\frac{r}{tan θ w} - f} \times θ w \qquad ( 4 )$$

From the above, in a case where x satisfies 0≤x<f−r, θt is set to satisfy the Equations (1) and (3). In a case where x satisfies f−r<x<r{(1/tan θw)−1}, θt is set to satisfy the Equations (2) and (4). As a result, it is possible to guide light L1 to optical waveguide 5 by inclined surface 71 while reducing the transmission of light L1 through peripheral wall 7.

With the configuration, even in a case where peripheral wall 7 has the light transmission, it is possible to efficiently guide light L1 to optical waveguide 5 by using the reflection on inclined surface 71. Therefore, it is not necessary to make precise adjustments in XYZ triaxial directions of light source 2, lens 4, and waveguide structure 3, and it is possible to suppress cost required for a structure of light emitting device 1 and manufacture of light emitting device 1, and, further, it is possible to improve the optical coupling efficiency. Further, even in a case where a semiconductor laser having individual spread angle θw is used as light source 2, it is possible to cause light L1 to be stably converged and incident on inlet 51 of optical waveguide 5, so that it is possible to reduce variation in the optical coupling efficiency.

### 2-2. Effects

In light emitting device 1 described above, in a case where the angle of the inclined surface of light L1 with respect to optical axis A1 is denoted by θt and the focal distance of lens 4 is denoted by f, x satisfies 0≤x<f−r and θt satisfies the following Equation.

$$0 ° < θ t < 45 ° - ( 1 - \frac{x}{f - r} ) \times \frac{θ w}{2}$$

As a result, it is possible to improve the light coupling efficiency.

Further, peripheral wall 7 has light transmission, and, in a case where the refractive index of peripheral wall 7 is denoted by n, θt satisfies the following Equation.

$$0 ° < θ t < 90 ° - arcsin \frac{1}{n} - ( 1 - \frac{x}{f - r} ) \times θ w$$

As a result, it is possible to improve the light coupling efficiency.

Further, in light emitting device 1, in a case where the angle of the inclined surface of light L1 with respect to optical axis A1 is denoted by θt and the focal distance of lens 4 is denoted by f, x satisfies f−r<x<r{1/tan θw−1} and θt satisfies the following Equation.

$$0 ° < θ t < 45 ° + \frac{x - f + r}{\frac{r}{tan θ w} - f} \times \frac{θ w}{2}$$

As a result, it is possible to improve the light coupling efficiency.

Further, peripheral wall 7 has light transmission, and, in a case where the refractive index of peripheral wall 7 is denoted by n, θt satisfies the following Equation.

$$0 ° < θ t < 90 ° - arcsin \frac{1}{n} + \frac{x - f + r}{\frac{r}{tan θ w} - f} \times θ w$$

As a result, it is possible to improve the light coupling efficiency.

### MODIFICATION EXAMPLE

The exemplary embodiments of the present disclosure are not limited to the exemplary embodiments. As long as the exemplary embodiments can achieve a task of the present disclosure, various changes are possible according to design and the like. Hereinafter, modification examples of the exemplary embodiments will be listed. The modification examples described hereinafter can be applied in combination as appropriate.

### 1. First Modification Example

FIG. 15 is a cross-sectional view of a configuration example of waveguide structure 3 of a first modification example. Waveguide structure 3 of FIG. 15 includes optical waveguide 5, exterior 6, and peripheral wall 7.

Peripheral wall 7 of FIG. 15 protrudes from a surface of exterior 6, from which inlet 51 is exposed, to the side of light emitting surface 21. Inner surface 71 of peripheral wall 7 of FIG. 15 includes first surface 71a and second surface 71b. First surface 71a is an inclined surface that inclines so that internal space 72 becomes narrower as approaching inlet 51. An inclination of the inclined surface is predetermined. Second surface 71b is a surface which extends from an opposite side of inlet 51 of first surface 71a, and a size of internal space 72 does not change even in a case of approaching inlet 51. In FIG. 15, not the entirety of inner surface 71 but a part thereof is the inclined surface. In FIG. 15, a part of internal space 72 has a truncated cone shape. As shown in FIG. 15, a diameter of a cross section of internal space 72 is the minimum at an end of first surface 71a on a side of inlet 51, and is the maximum at an end of first surface 71a on an opposite side of inlet 51 and second surface 71b. The maximum value of the diameter of the cross section of internal space 72 is smaller than diameter d of lens 4. In FIG. 15, adhesive 8 is applied to an edge an opening of internal space 72 of peripheral wall 7.

In waveguide structure 3 of FIG. 15, the entirety of peripheral wall 7 is narrow opening portion 7a in which internal space 72 of peripheral wall 7 is smaller than lens 4 when viewed from the direction of optical axis A1. At a part of narrow opening portion 7a, inner surface 71 of peripheral wall 7 is first surface 71a, which is an inclined surface that inclines so that internal space 72 becomes narrower as approaching inlet 51.

As being clear from the above, in waveguide structure 3, peripheral wall 7 may not include wide opening portion 7b. In waveguide structure 3, not the entirety of inner surface 71 of peripheral wall 7 but a part thereof may be the inclined surface that inclines so that internal space 72 becomes narrower as approaching inlet 51. Not in the entirety of narrow opening portion 7a but a part thereof, inner surface 71 of peripheral wall 7 may be the inclined surface that inclines so that internal space 72 becomes narrower as approaching inlet 51.

### 2. Second Modification Example

FIG. 16 is a cross-sectional view of a configuration example of a waveguide structure of a second modification example. Waveguide structure 3 of FIG. 16 includes optical waveguide 5, exterior 6, and peripheral wall 7.

Peripheral wall 7 of FIG. 16 protrudes from a surface of exterior 6, from which inlet 51 is exposed, to the side of light emitting surface 21. Inner surface 71 of peripheral wall 7 of FIG. 16 includes first surface 71a and second surface 71b. First surface 71a is an inclined surface that inclines so that internal space 72 becomes narrower as approaching inlet 51. An inclination of the inclined surface is predetermined. Second surface 71b is a surface which extends from an opposite side of inlet 51 of first surface 71a, and a size of internal space 72 does not change even in a case of approaching inlet 51. In FIG. 16, not the entirety of inner surface 71 but a part thereof is the inclined surface. In FIG. 16, a part of internal space 72 has a truncated cone shape. As shown in FIG. 16, a diameter of a cross section of internal space 72 is the minimum at an end of first surface 71a on the side of inlet 51 and is the maximum at an end of first surface 71a on an opposite side of inlet 51 and second surface 71b. A maximum value of the diameter of the cross section of internal space 72 is larger than diameter d of lens 4, and a minimum value of the diameter of the cross section of internal space 72 is smaller than diameter d of lens 4.

As above, peripheral wall 7 of FIG. 16 includes narrow opening portion 7a in which internal space 72 of peripheral wall 7 is smaller than lens 4 when viewed from the direction of optical axis A1. Peripheral wall 7 of FIG. 16 includes wide opening portion 7b in which internal space 72 of peripheral wall 7 is larger than lens 4 when viewed from the direction of optical axis A1. In FIG. 16, the entirety of lens 4 is accommodated in internal space 72 of peripheral wall 7. That is, lens 4 may not have a size contained in internal space 72 of peripheral wall 7. However, as long as lens 4 has the size contained in internal space 72, it is also possible to reduce the size of light emitting device 1 and light L1 is less likely to be leaked to an outside of peripheral wall 7. Inner surface 71 of peripheral wall 7 is an inclined surface that inclines so that internal space 72 becomes narrower as approaching inlet 51 in the entirety of narrow opening portion 7a.

As being clear from the above, in waveguide structure 3, not the entirety of inner surface 71 of peripheral wall 7 but a part thereof may be an inclined surface that inclines so that internal space 72 becomes narrower as approaching inlet 51. Inner surface 71 of peripheral wall 7 may be the inclined surface that inclines so that internal space 72 becomes narrower as approaching inlet 51 in the entirety of narrow opening portion 7a. The entirety of lens 4 may be accommodated in internal space 72 of peripheral wall 7.

### 3. Third Modification Example

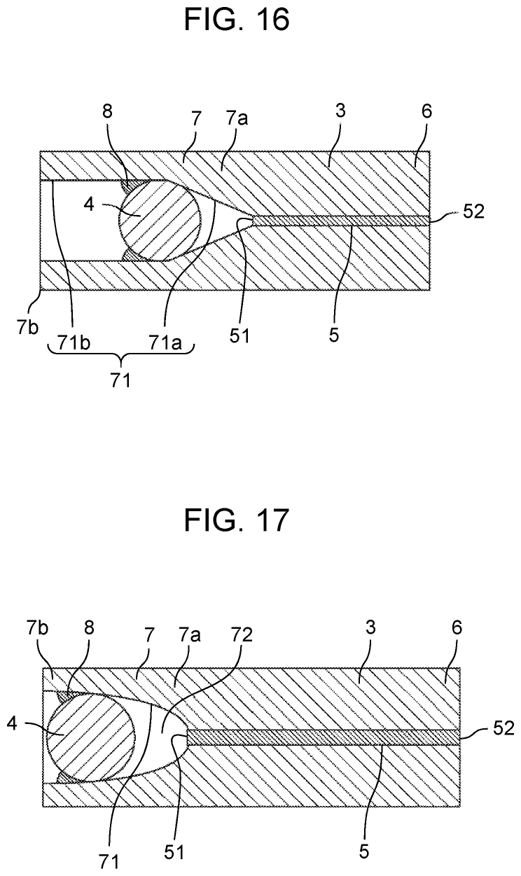

FIG. 17 is a cross-sectional view of a configuration example of a waveguide structure of a third modification example. Waveguide structure 3 of FIG. 17 includes optical waveguide 5, exterior 6, and peripheral wall 7.

Peripheral wall 7 of FIG. 17 protrudes from a surface of exterior 6, from which inlet 51 is exposed, to the side of light emitting surface 21. Inner surface 71 of peripheral wall 7 of FIG. 17 is an inclined surface that inclines so that internal space 72 becomes narrower as approaching inlet 51. In FIG. 17, the inclination of the inclined surface is not predetermined, and the inclined surface is a curved surface. In particular, the inclined surface is a concave curved surface whose inclination increases as approaching inlet 51. In FIG. 17, the entirety of inner surface 71 is the inclined surface. As shown in FIG. 17, a diameter of a cross section of internal space 72 is the minimum at an end of inner surface 71 on the side of inlet 51 and is the maximum at an end of inner surface 71 on an opposite side of inlet 51. A maximum value of the diameter of the cross section of internal space 72 is larger than diameter d of lens 4, and a minimum value of the diameter of the cross section of internal space 72 is smaller than diameter d of lens 4.

As above, peripheral wall 7 of FIG. 17 includes narrow opening portion 7a in which internal space 72 of peripheral wall 7 is smaller than lens 4 when viewed from the direction of optical axis A1. Peripheral wall 7 of FIG. 17 includes wide opening portion 7b in which internal space 72 of peripheral wall 7 is larger than lens 4 when viewed from the direction of optical axis A1. In FIG. 17, the entirety of lens 4 is accommodated in internal space 72 of peripheral wall 7. Inner surface 71 of peripheral wall 7 is an inclined surface that inclines so that internal space 72 becomes narrower as approaching inlet 51 in narrow opening portion 7a and the entirety of wide opening portion 7b.

As being clear from the above, in waveguide structure 3, the inclination of the inclined surface of inner surface 71 of peripheral wall 7 may not be predetermined and may be changed according to a distance from inlet 51. That is, the inclined surface may be a curved surface.

### 4. Other Modification Examples

In one modification example, instead of light source 2, an electromagnetic wave source that irradiates an electromagnetic wave having directivity may be adopted.

In one modification example, lens 4 is not limited to the spherical lens. Lens 4 is not limited to the spherical lens. A portion of lens 4 on the side of inlet 51 may be a convex lens. However, in a case where lens 4 is the spherical lens, center C1 of lens 4 is positioned on optical axis A1 of light L1 only by inserting lens 4 into internal space 72 of peripheral wall 7. Since the shape of lens 4 is spherical, adjustment, such as tilting, is not necessary. Lens 4 may have a polygonal shape, such as an elliptical shape or a regular polygonal shape, instead of a perfect circular shape, when viewed from the direction of optical axis A1.

In one modification example, in waveguide structure 3, internal space 72 may have a polygonal shape circumscribing lens 4, instead of the same shape as lens 4 when viewed from the direction of optical axis A1. As a result, lens 4 is easily positioned, so and it is possible to improve the optical coupling efficiency. Internal space 72 may have a regular polygonal shape when viewed from the direction of optical axis A1. In this case, a center of internal space 72 and a center of inlet 51 may coincide with each other when viewed from the direction of optical axis A1. As a result, lens 4 is easily positioned, so and it is possible to improve the optical coupling efficiency. In a case where internal space 72 has the perfect circular shape, it is easy to perform a process of forming internal space 72, thereby being suitable for processing the surface roughness for efficiently reflecting light L1. Further, the entirety of internal space 72 may not have the perfect circular shape or the regular polygonal shape, and internal space 72 may include the perfect circular shape or the regular polygonal shape when viewed from the direction of optical axis A1. For example, internal space 72 may be a space in which a portion contributing to the positioning of lens 4 has the perfect circular shape or the regular polygonal shape when viewed from the direction of optical axis A1. Similarly, even though the entirety of lens 4 does not have the perfect circular shape, lens 4 may include a portion having the perfect circular shape when viewed from the direction of optical axis A1. For example, in lens 4, a portion contributing to the positioning of waveguide structure 3 may have the perfect circular shape when viewed from the direction of optical axis A1.

In one modification example, optical waveguide 5 may have a cylindrical shape instead of the rectangular parallelepiped shape. In that case, both inlet 51 and outlet 52 have a circular shape.

In one modification example, exterior 6 may have the cylindrical shape instead of the rectangular parallelepiped shape.

In one modification example, peripheral wall 7 may be configured with a plurality of walls protruding from exterior 6 to surround inlet 51, instead of the tubular shape that surrounds inlet 51 over the entire circumference. That is, inner surface 71 of peripheral wall 7 may not be a continuous surface that surrounds inlet 51 over the entire circumference, and may be configured with a plurality of discrete surfaces that collectively surround inlet 51. In this case, internal space 72 of peripheral wall 7 is a space collectively surrounded by the plurality of surfaces configuring inner surface 71. The opening of peripheral wall 7 on the side of inlet 51 is a space collectively surrounded by edges of a plurality of surfaces configuring inner surface 71 on the side of inlet 51. The opening of peripheral wall 7 on the side of light emitting surface 21 is a space collectively surrounded by edges of the plurality of surfaces configuring inner surface 71 on the side of light emitting surface 21.

In one modification example, in internal space 72 of peripheral wall 7, not only inlet 51 of optical waveguide 5 but also a surface surrounding inlet 51 of exterior 6 may be exposed. However, in a case where light L1 reflected by the inclined surface of peripheral wall 7 is efficiently guided to optical waveguide 5, it is preferable that, in internal space 72 of peripheral wall 7, only inlet 51 of optical waveguide 5 is exposed.

In one modification example, inlet 51 may not have the rough surface. Inlet 51 may be coated to suppress the reflection of light L1.

In one modification example, the inclined surface itself of inner surface 71 of peripheral wall 7 may not have a mirror surface property. Inner surface 71 may be reflectively coated.

In one modification example, lens 4 may be fixed to waveguide structure 3 by a mechanical structure instead of adhesive 8.

In one modification example, the space surrounded by inlet 51, peripheral wall 7, and lens 4 may be a vacuum, or may be filled with a resin or the like for adjusting the refractive index.

In one modification example, optical waveguide 5 may not be formed of a material having light transmission, and may be hollow.

### ASPECTS

As being apparent from the exemplary embodiments and modification examples, the present disclosure includes the following aspects. Hereinafter, reference numerals are given in parentheses only to clearly indicate a correspondence relationship with the exemplary embodiments.

According to a first aspect, a light emitting device (1) includes a light source (2), a waveguide structure (3), and a lens (4). The light source (2) emits light (L1) having a directivity from a light emitting surface (21) of the light source (2). The waveguide structure (3) includes an optical waveguide (5) and a peripheral wall (7). The optical waveguide (5) includes an inlet (51) facing the light emitting surface (21). The peripheral wall (7) protrudes from the inlet (51) toward the light emitting surface (21). The peripheral wall (7) includes an inner surface (71) surrounding the inlet (51). The peripheral wall (7) has a first opening closer to the light emitting surface (21) and a second opening closer to the inlet (51). The first opening is larger than the second opening. The lens (4) is provided between the light emitting surface (21) and the inlet (51). The peripheral wall (7) includes a narrow opening portion (7a) in which an internal space (72) of the peripheral wall (7) is smaller than the lens (4) when viewed from a direction of an optical axis (A1) of the light (L1). The inner surface (71) of the peripheral wall (7) inclines an inclined surface (71: 71a) so that the internal space (72) becomes narrower as approaching the inlet (51), at least in the narrow opening portion (7a). The lens (4) is disposed in contact with the narrow opening portion (7a) in the internal space (72) of the peripheral wall (7). According to the aspect, the lens (4) can be easily positioned, so that it is possible to improve the optical coupling efficiency.

A second aspect is the light emitting device (1) based on the first aspect. In the second aspect, a portion of the lens (4) on the side of the inlet is a convex lens. According to the aspect, the lens (4) can be easily positioned, so that it is possible to improve the optical coupling efficiency.

A third aspect is the light emitting device (1) based on the second aspect. In the third aspect, the internal space (72) has the same shape as a shape of the lens (4) or a polygonal shape circumscribing the lens (4) when viewed from the direction of the optical axis (A1). According to the aspect, the lens (4) can be easily positioned, so that it is possible to improve the optical coupling efficiency.

A fourth aspect is the light emitting device (1) based on the second or third aspect. In the fourth aspect, the lens (4) includes a portion having a perfect circular shape when viewed from the direction of the optical axis (A1). The internal space (72) includes a space having a perfect circular shape or a regular polygonal shape when viewed from the direction of the optical axis (A1). When viewed from the direction of the optical axis (A1), a center of the internal space (72) coincide with a center of the inlet (51). According to the aspect, the lens (4) can be easily positioned, so that it is possible to improve the optical coupling efficiency.

A fifth aspect is the light emitting device (1) based on any one of the second to fourth aspects. In the fifth aspect, the lens (4) is a spherical lens. According to the aspect, the lens (4) can be easily positioned, so that it is possible to improve the optical coupling efficiency.

A sixth aspect is the light emitting device (1) based on the fifth aspect. In the sixth aspect, in a case where a distance from the light emitting surface (21) of the light source (2) to the lens (4) on the optical axis (A1) of the light (L1) is denoted by x, a spread angle of the light (L1) is denoted by θw, and a radius of the lens (4) is denoted by r, x satisfies 0≤x<r{(1/tan θw)−1}. According to the aspect, it is possible to improve the optical coupling efficiency.

A seventh aspect is the light emitting device (1) based on the sixth aspect. In the seventh aspect, in a case where an angle of the inclined surface with respect to the optical axis (A1) of the light (L1) is denoted by θt and a focal distance of the lens (4) is denoted by f, x satisfies 0≤x<f−r and θt satisfies the following Equation.

$$0 ° < θ t < 45 ° - ( 1 - \frac{x}{f - r} ) \times \frac{θ w}{2}$$

According to the aspect, it is possible to improve the optical coupling efficiency.

An eighth aspect is the light emitting device (1) based on the seventh aspect. In the eighth aspect, the peripheral wall (7) has light transmittance, and, in a case where a refractive index of the peripheral wall (7) is denoted by n, θt satisfies the following Equation.

$$0 ° < θ t < 90 ° - arcsin \frac{1}{n} - ( 1 - \frac{x}{f - r} ) \times θ w$$

According to the aspect, it is possible to improve the optical coupling efficiency.

A ninth aspect is the light emitting device (1) based on the sixth aspect. In the ninth aspect, in a case where an angle of the inclined surface with respect to the optical axis (A1) of the light (L1) is denoted by θt and a focal distance of the lens (4) is denoted by f, x satisfies f−r≤x<r{(1/tan θw)−1} and θt satisfies the following Equation.

$$0 ° < θ t < 45 ° + \frac{x - f + r}{\frac{r}{tan θ w} - f} \times \frac{θ w}{2}$$

According to the aspect, it is possible to improve the optical coupling efficiency.

A tenth aspect is the light emitting device (1) based on the ninth aspect. In the tenth aspect, the peripheral wall (7) has light transmission, and, in a case where a refractive index of the peripheral wall (7) is denoted by n, θt satisfies the following Equation.

$$0 ° < θ t < 90 ° - arcsin \frac{1}{n} + \frac{x - f + r}{\frac{r}{tan θ w} - f} \times θ w$$

According to the aspect, it is possible to improve the optical coupling efficiency.

An eleventh aspect is the light emitting device (1) based on any one of the first to tenth aspects. In the eleventh aspect, an entirety of the inner surface (71) of the peripheral wall (7) is the inclined surface (71). According to the aspect, it is possible to simplify a structure of the waveguide structure(3), and it is possible to reduce manufacturing cost of the light emitting device (1).

A twelfth aspect is the light emitting device (1) based on any one of the first to eleventh aspects. In the twelfth aspect, the inlet (51) has a rough surface. According to the aspect, it is possible to improve an absorption efficiency of the optical waveguide (5) with respect to light L3.

A thirteenth aspect is the light emitting device (1) based on the twelfth aspect. In the thirteenth aspect, surface roughness of the inlet (51) is larger than 0.2 μm and is equal to or less 20 μm. According to the aspect, it is possible to improve the absorption efficiency of the optical waveguide (5) with respect to light L3.

A fourteenth aspect is the light emitting device (1) based on any one of the first to thirteenth aspects. In the fourteenth aspect, the inclined surface (71; 71a) has a mirror surface property. According to the aspect, it is possible to improve reflection efficiency of the inclined surface (71; 71a) with respect to light (L3).

A fifteenth aspect is the light emitting device (1) based on the fourteenth aspect. In the fifteenth aspect, surface roughness of the inclined surface (71; 71a) is equal to or less than 0.2 μm. According to the aspect, it is possible to improve the reflection efficiency of the inclined surface (71; 71a) with respect to the light (L3).

A sixteenth aspect is the light emitting device (1) based on any one of the first to fifteenth aspects. In the sixteenth aspect, the light source (2) is a semiconductor laser, and the light (L1) is a laser beam (L1). According to the aspect, it is possible to miniaturize the light emitting device (1).

A seventeenth aspect is the light emitting device (1) based on any one of the first to sixteenth aspects. In the seventeenth aspect, the lens (4) is fixed to the waveguide structure (3) with an adhesive (8). According to the aspect, position shift between the lens (4) and the waveguide structure (3) is less likely to occur during the use of the light emitting device (1), and it is possible to stabilize the optical coupling efficiency of the light emitting device (1) for a long period of time.

An eighteenth aspect is the light emitting device (1) based on the seventeenth aspect. In the eighteenth aspect, the adhesive (8) is applied to surround the lens (4) as a whole when viewed from the direction of the optical axis (A1). According to the aspect, position shift between the lens (4) and the waveguide structure (3) is less likely to occur, so that it is possible to prevent invasion of a minute foreign matter into the space surrounded by the inlet (51), the peripheral wall (7), and the lens (4).

A nineteenth aspect is the light emitting device (1) based on the seventeenth or eighteenth aspect. In a nineteenth aspect, the peripheral wall (7) includes a wide opening portion (7b) in which the internal space (72) is larger than the lens (4) when viewed from the direction of the optical axis (A1) of the light (L1). The adhesive (8) is disposed between the lens (4) and the wide opening portion (7b) of the peripheral wall (7). According to the aspect, it is possible to reduce disturbance of reflection of light (L1) in the space surrounded by inlet (51), peripheral wall (7), and lens (4).

A twentieth aspect is the light emitting device (1) based on any one of the first to nineteenth aspects. In the twentieth aspect, a space surrounded by the inlet (51), the peripheral wall (7), and the lens (4) is filled with gas. According to the aspect, it is possible to reduce disturbance of reflection of light (L1) in the space surrounded by inlet (51), peripheral wall (7), and lens (4).

According to a twenty first aspect, there is provided is a manufacturing method for manufacturing the light emitting device (1) based on any one of the first to twentieth aspects, the manufacturing method includes disposing (S2) the lens (4) so that the lens (4) is in contact with the narrow opening portion (7a) in the internal space (72) of the peripheral wall (7) of the waveguide structure (3), and disposing (S4) the waveguide structure (3) so that the inlet (51) of the optical waveguide (5) of the waveguide structure (3) faces the light emitting surface (21) of the light source (2) via the lens (4). According to the aspect, the lens (4) can be easily positioned, so that it is possible to improve the optical coupling efficiency.

A twenty second aspect is a waveguide structure (3) including an optical waveguide (5) and a peripheral wall (7). The optical waveguide (5) includes an inlet (51) that faces a light emitting surface (21), from which light (L1) having a directivity is emitted, of a light source (2) while interposing a lens (4) therebetween. The peripheral wall (7) protrudes from the inlet (51) toward the light emitting surface (21). The peripheral wall (7) includes an inner surface (71) surrounding the inlet (51). The peripheral wall (7) has a first opening closer to the light emitting surface (21) and a second opening closer to the inlet (51). The first opening is larger than the second opening. The peripheral wall (7) includes a narrow opening portion (7a) in which an internal space (72) of the peripheral wall (7) is smaller than the lens (4) when viewed from a direction of an optical axis (A1) of the light (L1). The inner surface (71) of the peripheral wall (7) inclines an inclined surface (71: 71a) so that the internal space (72) becomes narrower as approaching the inlet (51), at least in the narrow opening portion (7a). According to the aspect, the lens (4) can be easily positioned, so that it is possible to improve the optical coupling efficiency.

As above, the exemplary embodiments have been described as examples of a technique of the present disclosure. For this, the accompanying drawings and the detailed description are provided. Therefore, components described in the accompanying drawings and the detailed description may include not only the components essential for solving the problem but also the components not essential for solving the problem in order to exemplify the technique. Therefore, the fact that the non-essential components are described in the accompanying drawings and the detailed description should not be directly recognized that the non-essential components are essential. Further, since the above-described exemplary embodiments are for exemplifying the technique of the present disclosure, various changes, replacements, additions, omissions, and the like can be made within the scope of claims or the equivalent scope thereof.

It is possible to apply the present disclosure to a light emitting device. Specifically, it is possible to apply the present disclosure to a light emitting device including a light source that emits light having directivity. Further, it is possible to apply the present disclosure to an irradiation device that irradiates an electromagnetic wave having directivity.

What is claimed is:

1. A light emitting device comprising:
a light source that emits light having a directivity from a light emitting surface of the light source;
a waveguide structure that includes
an optical waveguide having an inlet facing the light emitting surface, and
a peripheral wall protruding from the inlet toward the light emitting surface and having an inner surface surrounding the inlet, the peripheral wall having a first opening closer to the light emitting surface and a second opening closer to the inlet, the first opening being larger than the second opening; and
a lens that is provided between the light emitting surface and the inlet, wherein
the peripheral wall includes a narrow opening portion in which an internal space of the peripheral wall is smaller than the lens when viewed from a direction of an optical axis of the light,
the inner surface of the peripheral wall includes an inclined surface that inclines so that the internal space becomes narrower as approaching the inlet, at least in the narrow opening portion, and
the lens is disposed in contact with the narrow opening portion in the internal space of the peripheral wall.

2. The light emitting device of claim 1, wherein
a portion of the lens on the side of the inlet is a convex lens.

3. The light emitting device of claim 2, wherein
the internal space has the same shape as a shape of the lens or a polygonal shape circumscribing the lens when viewed from the direction of the optical axis.

4. The light emitting device of claim 2, wherein
the lens includes a portion having a perfect circular shape when viewed from the direction of the optical axis,
the internal space includes a space having a perfect circular shape or a regular polygonal shape when viewed from the direction of the optical axis, and
a center of the internal space coincides with a center of the inlet when viewed from the direction of the optical axis.

5. The light emitting device of claim 2, wherein
the lens is a spherical lens.

6. The light emitting device of claim 5, wherein
in a case where a distance from the light emitting surface of the light source to the lens on the optical axis of the light is denoted by x,
a spread angle of the light is denoted by θw, and
a radius of the lens is denoted by r,
x satisfies 0≤x<r{(1/tan θw)−1}.

7. The light emitting device of claim 6, wherein
in a case where an angle of the inclined surface with respect to the optical axis of the light is denoted by θt, and
a focal distance of the lens is denoted by f,
x satisfies 0≤x<f−r, and
θt satisfies the following Equation.
$$0 ° < θ t < 45 ° - ( 1 - \frac{x}{f - r} ) \times \frac{θ w}{2}$$

8. The light emitting device of claim 7, wherein
the peripheral wall has light transmission, and
in a case where a refractive index of the peripheral wall is denoted by n, θt satisfies the following Equation.
$$0 ° < θ t < 90 ° - arcsin \frac{1}{n} - ( 1 - \frac{x}{f - r} ) \times θ w$$

9. The light emitting device of claim 6, wherein
in a case where an angle of the inclined surface with respect to the optical axis of the light is denoted by θt, and
a focal distance of the lens is denoted by f,
x satisfies f−r≤x<r{(1/tan θw)−1}, and
θt satisfies the following Equation.
$$0 ° < θ t < 45 ° + \frac{x - f + r}{\frac{r}{tan θ w} - f} \times \frac{θ w}{2}$$

10. The light emitting device of claim 9, wherein
the peripheral wall has light transmission, and
in a case where a refractive index of the peripheral wall is denoted by n, θt satisfies the following Equation.
$$0 ° < θ t < 90 ° - arcsin \frac{1}{n} + \frac{x - f + r}{\frac{r}{tan θ w} - f} \times θ w$$

11. The light emitting device of claim 1, wherein
an entirety of the inner surface of the peripheral wall is the inclined surface.

12. The light emitting device of claim 1, wherein
the inclined surface has a mirror surface property.

13. The light emitting device of claim 12, wherein
surface roughness of the inclined surface is equal to or less than 0.2 μm.

14. The light emitting device of claim 1, wherein
the light source is a semiconductor laser, and
the light is a laser beam.

15. The light emitting device of claim 1, wherein
the lens is fixed to the waveguide structure with an adhesive.

16. The light emitting device of claim 15, wherein
the adhesive is applied to surround the lens as a whole when viewed from the direction of the optical axis.

17. The light emitting device of claim 15, wherein
the peripheral wall includes a wide opening portion in which the internal space is larger than the lens when viewed from the direction of the optical axis of the light, and
the adhesive is disposed between the lens and the wide opening portion of the peripheral wall.

18. The light emitting device of claim 1, wherein
a space surrounded by the inlet, the peripheral wall, and the lens is filled with gas.

19. A manufacturing method for manufacturing the light emitting device of claim 1, the manufacturing method comprising:
disposing the lens so that the lens is in contact with the narrow opening portion in the internal space of the peripheral wall of the waveguide structure, and
disposing the waveguide structure so that the inlet of the optical waveguide of the waveguide structure faces the light emitting surface of the light source via the lens.

20. A waveguide structure comprising:
an optical waveguide including an inlet that faces a light emitting surface, from which light having a directivity is emitted, of a light source while interposing a lens therebetween; and
a peripheral wall protruding from the inlet toward the light emitting surface and having an inner surface surrounding the inlet, the peripheral wall having a first opening closer to the light emitting surface and a second opening closer to the inlet, the first opening being larger than the second opening, wherein
the peripheral wall includes a narrow opening portion in which an internal space of the peripheral wall is smaller than the lens when viewed from a direction of an optical axis of the light, and
the inner surface of the peripheral wall includes an inclined surface that inclines so that the internal space becomes narrower as approaching the inlet, at least in the narrow opening portion.
